(19) United States
(12) Patent Application Publication
(10) Pub. No.: US 2007/0022331 A1
(43) Pub. Date: Jan. 25, 2007

(54) Single-ended ethernet management system and method

(75) Inventors: Ross Alexander Jamieson, Plano, TX (US); John Kevin Weeks, Richardson, TX (US); Paul Anthony Elias, Richardson, TX (US); Michael Joseph Mezeul, Allen, TX (US); Wayne Robert Sankey, Plano, TX (US); Hamid Reza Rezaie, Dallas, TX (US); James Buchanan, Ottawa (CA)

Correspondence Address: HAYNES AND BOONE, LLP, 901 MAIN STREET, SUITE 3100, DALLAS, TX, 75202, US

(73) Assignee: Covaro Networks, Inc., Richardson, TX (US)

(21) Appl. No.: 10/369,411

(22) Filed: Feb. 18, 2003

Related U.S. Application Data
(60) Provisional application No. 60/431,912, filed on Dec. 9, 2002.

(51) Int. Cl. G01R 31/28

(52) U.S. Cl. 714/712

(57) ABSTRACT

A single-ended Ethernet management system and method are provided. The system enables a user to provision and monitor an Ethernet interface, as well as to detect and isolate faults, from a single end. The method may be executed on the system to provide Ethernet services from a first end to a second end. After the Ethernet service is established, the method monitors the service from the first end to detect an occurrence of a fault and to identify service degradation issues. If a fault occurs, the method automatically executes a fault isolation procedure to isolate a location of the fault between the first and second ends. In addition, the method may categorize one or more potential causes for the fault based on fault location or type.

### CROSS-REFERENCE

This application claims priority from U.S. Provisional Patent Application Ser. No. 60/431,912, filed on Dec. 9, 2002.

### BACKGROUND

The present disclosure relates generally to communication services and, more specifically, to a system and method for deploying and managing Ethernet services.

Communication companies using systems that incorporate Ethernet face a number of difficulties in managing their systems. These difficulties are generally caused by a lack of features in Ethernet standards and devices that would enable Ethernet services to be deployed in carrier-class fashion. For example, Ethernet generally requires multi-pair copper wire (e.g., Category 5 (CAT 5) cable) for 10/100 Base-T interfaces. However, copper-based Ethernet interfaces have distance limitations (approximately 100 meters over CAT 5 cabling) and there is generally no ability to diagnose cable faults for copper-based Ethernet links. In addition, there are limited carrier-class performance monitoring and diagnostic capabilities on Ethernet links. Existing monitoring and diagnostic procedures frequently utilize complex provisioning commands via non-standard-based command line interfaces or graphical user interfaces (GUIs) and require the human user to follow a sequence of manual trouble shooting steps. In addition, a Simple Network Management Protocol (SNMP) operations support system (OSS) overlay is needed to monitor Ethernet performance.

Diagnosis of problems frequently requires an operator or technician to log in to both sides of an Ethernet link, which not only adds complexity to trouble shooting, but may be difficult or impossible if the opposite end comprises a customer's equipment. As end-to-end diagnosis of Ethernet connections is not generally possible from a single end, fault isolation frequently entails sending a technician down a “chain” of designated points in a network until the location of the fault is isolated. This is both time consuming and costly.

Accordingly, what is needed is a system and method for single-ended provisioning, monitoring, and testing of Ethernet services. In addition, it is desirable to provide carrier-class services over a plurality of media types.

### SUMMARY

A technical advance is provided by a method and system for detecting and diagnosing a fault in an Ethernet service interface. The fault is detected and diagnosed from a first point in a communications link, where the communications link includes the Ethernet service interface and terminates at a second point. The method comprises monitoring the link from the first point to detect an occurrence of the fault, where the fault occurs between the first and second points. At least one fault attribute is identified when the fault is detected, where the fault attribute is identified from the first point, and one or more potential causes for the fault are categorized based on the identified fault attribute.

### BRIEF DESCRIPTION OF THE DRAWINGS

FIG. 1 is a flow chart illustrating a method for establishing, managing, and isolating faults from a single end of an Ethernet connection.

FIG. 2 is an exemplary network in which the method of FIG. 1 may be implemented.

FIGS. 3 and 4 are a flow chart illustrating another embodiment of a method for establishing, managing, and isolating faults from a single end of an Ethernet connection in the network of FIG. 2.

FIG. 5 is another exemplary network in which the method of FIG. 1 may be implemented.

FIGS. 6 and 7 are a flow chart illustrating another embodiment of a method for establishing, managing, and isolating faults from a single end of an Ethernet connection in the network of FIG. 5.

FIG. 8 illustrates one embodiment of a exemplary system for remotely switching a line status between terminated and non-terminated.

FIGS. 9 and 10 illustrate another embodiment of an exemplary system for remotely switching a line status between terminated and non-terminated

### DETAILED DESCRIPTION

The present disclosure relates generally to communication services and, more specifically, to a system and method for deploying and managing Ethernet services. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

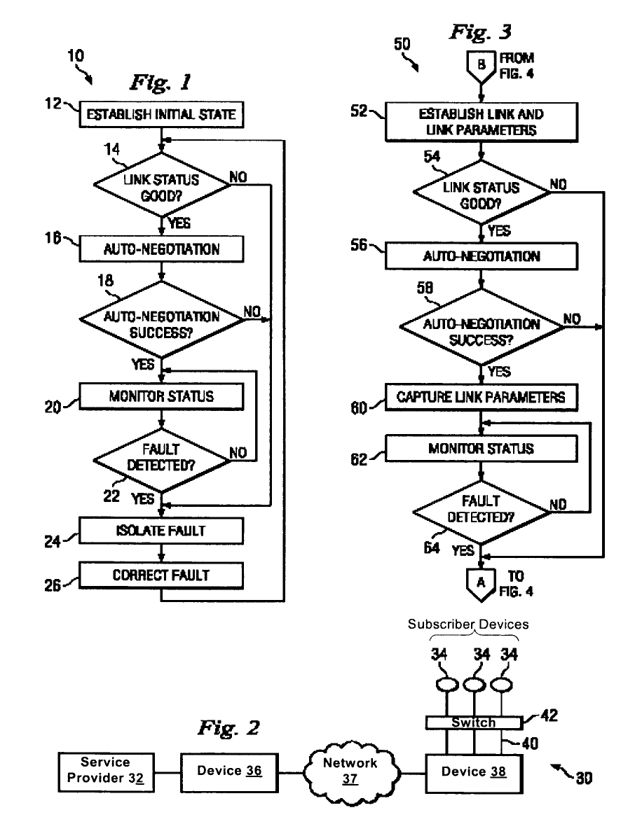

Referring to FIG. 1, in one embodiment, a method 10 is operable to provide pre-service, in-service, and out-of-service Ethernet capabilities from a single end of a network. As will be described later in greater detail, this enables a service provider to provision and monitor an Ethernet service interface, as well as detect and diagnose faults in the Ethernet service interface in a cost-effective manner. Such functionality may be achieved, for example, by using cable-testing equipment to add monitoring and diagnostic capabilities to legacy equipment for end-to-end services.

In step 12, an initial state is established. This may include, for example, establishing a link, checking a status of the link, verifying service, testing cable length, obtaining service parameters, and similar actions. In step 14, a determination is made as to whether the link status meets certain predefined performance criteria. If the link status fails, the method 10 jumps to step 24, where an attempt is made to isolate the fault. The method 10 then continues to step 26, where the fault is corrected. The type of correction may depend on the fault, and may range from the activation of automatic correction procedures to initiating a truck roll to send a technician to a location where the fault was diagnosed. The method 10 then returns to step 14.

If the link status passes step 14, the method 10 continues to step 16 where an auto-negotiation process occurs. If the auto-negotiation process fails, as determined in step 18, the method 10 jumps to steps 24 and 26 to isolate and correct the fault. If the auto-negotiation is successful, the method 10 continues to step 20, where it monitors the link for faults, service degradation, and other problems. The monitoring may include comparing current service conditions (e.g., packet loss) to a predefined set of parameters. If a fault occurs, as determined in step 22, the method 10 continues to steps 24 and 26 to isolate and correct the fault. Accordingly, the method enables a problem in an Ethernet connection to be identified and isolated from a single end of the Ethernet connection (e.g., from a service provider's end).

Referring now to FIG. 2, an exemplary network 30 provides a framework within which the method 10 of FIG. 1 may be executed to provide Ethernet services from a service provider 32 to a plurality of subscriber devices 34. The service provider 32 may be located at a central office or a similar point of presence that is connected to the network 30 through a device 36, such as a Synchronous Optical Network (SONET) add/drop multiplexer (ADM), which forms part of a SONET network 37. The device 36 is connected via fiber optics to another device 38, which is located relatively close to the subscriber devices 34 due to distance limitations imposed by Ethernet connectivity. The device 38, which incorporates SONET ADM technology, is operable to separate data intended for the subscriber devices 34 from other data being transported through the SONET network, as well as to add data from the subscriber devices 34 before passing it to the device 36. The device is connected to the subscriber devices 34 through cabling 40 appropriate for Ethernet communications (e.g., Category 5 (CAT 5) cable). Each cable may be connected to a layer 2 (L2) switch 42 that serves to terminate the Ethernet services at each subscriber device 34. In addition, time domain reflectometers (TDRs) (not shown) may be deployed either between the device 38 and the L2 switch 42 or within the device 38 itself. The TDRs aid in fault isolation along the cables 40 and associated devices 34, 38.

In the present example, the device 38 includes a plurality of 10/100BaseT Ethernet ports (not shown), which are provided as a module. These Ethernet ports enable the subscriber devices 34 to connect directly to the device 38 via a standard Ethernet cable (10BaseTX, 100BaseTX). In this direct-connect mode, commonly available Ethernet physical layers (PHYs) associated with the device 38 Ethernet ports may provide enhanced visibility of link conditions and performance monitoring on the Ethernet ports. The Ethernet ports are modeled as client ports.

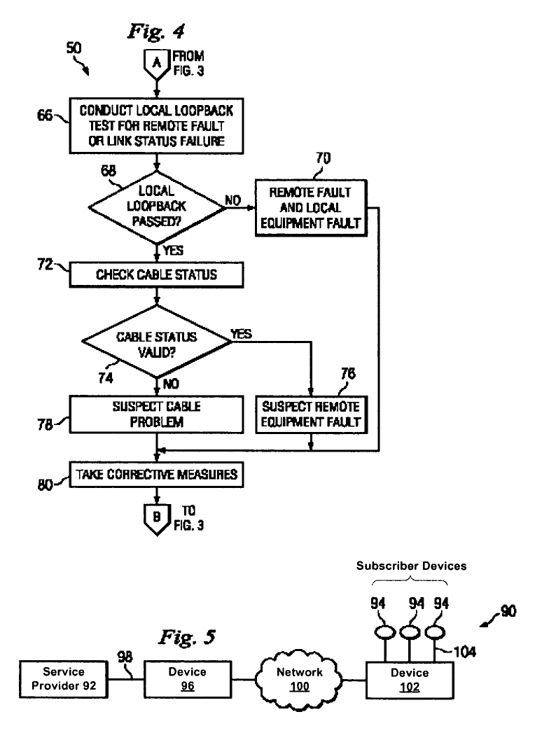

Referring now to FIGS. 3 and 4, in another embodiment, a method 50 utilizes steps 52-78 to enable single-ended management of the device 38 and associated components by the service provider 32 to initialize, monitor, and diagnose problems with an Ethernet service interface as follows. In the present example, the method 50 is implemented by extending the capabilities provided by Transaction Language 1 (TL1) commands in data transport services. A more detailed description of specific commands and associated information is disclosed in U.S. Provisional Patent Application Ser. No. (Attorney Docket No. 31873.18), filed on Dec. 9, 2002, and hereby incorporated by reference as if reproduced in its entirety. Other management interfaces and protocols may also be used, such as SNMP, CLI, CORBA, CMISE, and GUI.

Beginning in step 52, a link is established and link parameters are determined. This may include provisioning the Ethernet module (e.g., by using an ENT-EQPT command) and provisioning the Ethernet service interface (e.g., by using an ENT-E100 command), with port parameters defaulting to predetermined values. An Ethernet service is created by connecting one of the interfaces to a transport facility (e.g., the device 36). Other capabilities may be defined, such as control of over-subscription (e.g., where the bandwidth needed by services/subscribers exceeds the capacity of the network) and port parameters (e.g., a port rate limit).

Before the Ethernet interface is placed in-service, the method 50 determines a current link status (e.g., good or bad) in step 54. If the link status is bad, the method 50 enters a fault isolation stage, which will be described later with respect to FIG. 4. If the link status if good, the method 50 continues to step 56, where an auto-negotiation procedure is initiated. If the auto-negotiation is not successful, as determined in step 58, the method 50 continues to the fault isolation stage of FIG. 4. If the auto-negotiation is successful, the method 50 continues to step 60, where link parameters (e.g., cable status and cable length) are captured. The captured parameters may be used for future fault isolation purposes. For example, the captured cable length may be used in future fault reports to determine whether to report failures as “near end” (e.g., the end on the service provider's equipment, device 38) or “far end” (e.g., the end on the subscriber devices 34).

Although not shown, prior to placing the Ethernet interface in service, other steps may be executed. For example, if the Ethernet interface supports remote fault indication during auto-negotiation, then the method 50 may check for such an indicator. Furthermore, the present method 50 incorporates Automatic IN-Service (AINS), which allows an operator to place an Ethernet port in the in-service state prior to a physical cable being attached to the port. Any alarms on the port will be squelched until the method 50 has detected a valid signal on the port for some predefined period of time (e.g., ten seconds). Once the period of time has elapsed, the port will revert to normal operating mode and will report alarms.

Once the Ethernet interface is placed in service, the method 50 continues to steps 62, 64 and performs monitoring operations. The monitoring may check for link failure, loss of carrier and/or signal, low light conditions (for fiber optic interfaces), restart of auto-negotiation, remote fault indication, and faults, such as those generated by incorrect link parameters (e.g., cable status and length). The monitoring may also check for other faults and service degradation issues, as well as collect statistics for trend analysis. If a fault is detected in step 64, the method transitions to an out-of-service autonomous state (OOS-AU) and continues to step 66 of FIG. 4 to attempt to isolate the fault.

It is understood that some tests may occur while the Ethernet interface is in service, while other tests may require that the interface be removed from service (e.g., disruptive testing). For example, in the present example, in-service testing may occur for testing cable length during regular operation in 100/1000 Mbps modes. Out-of-service testing may allow the testing of the device 38 and its associated ports, and cables leading to the device 38. Furthermore, out-of-service testing may test equipment output transmitters and input receivers via internal loopback, as well as perform both terminated and non-terminated Ethernet cable problem analysis. Non-terminated analysis includes, for example, fault isolation along a cable and, for each cable connected to a port, identifying open circuits, short circuits, and impedance mismatches. Estimation of cable length on a properly terminated cable can be used to identify the location of a subsequent fault.

Referring now to FIG. 4 and with continued reference to FIG. 3, one or more tests are run automatically to determine whether the fault detected in step 64 is due to a local equipment failure, remote equipment failure, or a cable problem. In step 66, a local loopback test is conducted on the local equipment. If it is determined in step 68 that the local loopback test has failed, then the fault is likely due to a local equipment failure as indicated by step 70. Corrective measures may be taken and the method 50 returns to step 56.

If the local loopback test passes, then the fault is not in the local equipment and the method 50 continues to step 72, where a cable status check is made. The cable status may be determined using, for example, Ethernet PHYs with integrated TDR capability or standalone TDRs as described with respect to FIG. 2 and may be caused by a number of problems. For example, an invalid Ethernet cable length may be caused by an improper termination, while a change in cable length from an initially characterized value (obtained in step 60) may indicate a change to the cable (e.g., the addition of a bad cable segment). If it is determined in step 74 that the cable status is not valid (e.g., the cable is disconnected or broken), then the fault is likely due to a cable problem, as indicated in step 78. If the cable status is valid, then the fault is likely due to a remote equipment failure. Corrective measures may be taken in step 80 and the method 50 returns to step 52. It is understood that FIG. 4 may be expanded to encompass a variety of failure scenarios, such as auto-negotiation failure.

Accordingly, the method 50 of FIGS. 3 and 4 utilizes components of the network 30 of FIG. 2 to provide and manage Ethernet services. Furthermore, the method 50 enables the detection and isolation of faults to enable the service provider 32 to rapidly identify and address disruptions and potential disruptions to the Ethernet service. After a fault is detected and isolated, a detailed report may be generated regarding the fault, various fault attributes (e.g., type, location), and similar information.

Referring now to FIG. 5, in yet another embodiment, an exemplary network 90 provides a framework within which the method 10 of FIG. 1 may be executed to provide Ethernet services from a service provider 92 to a plurality of subscriber devices 94. The service provider 92 is connected to a device 96 through a SONET-based fiber optic connection 98. The device 96 is operable to connect the service provider 92 to a device 102 (e.g., a media converter) through a copper wire network 100 using, for example, an Ethernet Media eXtension (EMX) service in which Ethernet frames are carried over the copper wire network 100. The network 100 in the present example is the local loop plant comprised of twisted copper pairs , such as is known in the art.

The device 102 includes an interface (e.g., a modem) for communicating via digital subscriber line (e.g., DSL, SHDSL, VDSL; which are herein referred to collectively as DSL) with the device 96, and an Ethernet interface for providing Ethernet services to the subscriber devices 94 via Ethernet compatible cabling 104. The device 102 presents the subscriber devices 94 with 10/100BaseT interface ports and may use DSL technologies on a wide area network (WAN) interface to extend the reach of an Ethernet link up to several thousand feet. If a WAN interface is provided, the device 102 provides enhanced visibility of loop conditions and performance monitoring on the device's subscriber Ethernet ports, as well as enhanced WAN link management via DSL loop management techniques and embedded management channels. In this manner, problems associated with the WAN extension may be diagnosed and single ended management features may be implemented on the client interface.

In the present example, both the Ethernet and DSL interfaces provide their respective ports through modules. The Ethernet ports are modeled as client ports and, to activate the ports, the Ethernet module is first provisioned (either manually or automatically). The Ethernet ports on the module may then be provisioned.

In the present example, each of the Ethernet ports may be associated with AINS, which enables the Ethernet port to be preprovisioned in a ready state prior to a physical cable being attached to the port. Any alarms on the Ethernet port will be squelched until a valid signal has been detected on the port for a predetermined period of time (e.g., ten seconds). Once the period of time has elapsed, the Ethernet port will revert to normal operating mode and will report alarms.

The device 102 may also conduct automatic Ethernet fault isolation upon detection of a failure using cable and equipment diagnostic features, which will be described in greater detail in the following text. For example, when a link fault is detected between the subscriber equipment and device 102, automatic isolation diagnostics may attempt an equipment port loopback at device 102 to check transmitter and receiver functions. If no transmitter or receiver faults are detected, a loop fault would be reported. In addition, the device 102 may extend Ethernet services to carrier serving area ranges and hide details of DSL link management from an operator. Accordingly, due to the system automatically provisioning the DSL link, there is no need to manually provision the DSL link when creating “remote” Ethernet ports.

The Ethernet ports may raise alarms on detecting predefined conditions or events. For example, an alarm may be raised on the basis of a link fault, a jabber (e.g., a condition where a station transmits for a period of time longer than the permissible packet length) receive, or a remote fault. These alarms are reported from the device 102 to the device 96 which reports them to the operator 92.

A DSL link and port implemented via the device 102's DSL interface (and module) may also be the source of faults. For example, the device 102 may monitor the DSL interface for alarm conditions such as loss of signal, loss of synchronization, and loop attenuation defects (e.g., where a loop attenuation threshold is exceeded). DSL port and equipment failures may raise alarms associated with network termination, loss of power, modem fault, port module removal (e.g., the module terminating the port is removed), and mismatched provisioning (e.g., there is a module provisioning mismatch with the physical module present in a slot).

Performance monitoring may occur at two points. Firstly, EtherStat performance monitoring may be conducted on the Ethernet ports at device 102 to allow the service provider to monitor the subscriber device's incoming traffic conditions at a predefined demarcation point. Secondly, the DSL link may be monitored at both the device 96 and the device 102 to provide information relating to the condition and performance of the digital local loop between the service provider 96 and the subscriber devices 102. Statistical data may be collected as previously described. For example, periodic reports may be generated that detail the status of both the DSL and Ethernet links over time.

Performance of the DSL link is monitored for both upstream and downstream directions. In the downstream direction, the modem associated with the device 102 collects performance counts which are forwarded to the device 96. In the upstream direction, the DSL link is monitored at the termination point on the DSL module. Performance monitoring may collect a variety of different statistics, as are disclosed in previously incorporated U.S. Provisional Patent Application Ser. No. (Attorney Docket No. 31873.18).

When delivering Ethernet services over DSL media, the DSL loop may be non-terminated (e.g., the device 102 is not present or not physically connected) or the device 102 may be present and physically connected. The loop may be non-terminated in cases where an operator connects a non-terminated loop to a port to perform single-ended loop qualification diagnostics. In this case, an operator may issue a diagnose command against the device 96, which enables the operator to characterize/test the DSL loop during pre-service activation. If the device 102 is physically connected and provisioned (e.g., a service is or has been running and a diagnostic is required to isolate a fault condition), the operator issues the diagnose command against the device 102 (to diagnose an Ethernet port problem) or against the Ethernet service connected to the device 102 (to diagnose a DSL line problem).

As previously described, some diagnostic tests may be executed while a connection is in-service, while others require that the connection be placed out-of-service. In-service diagnostics on the Ethernet ports of the device 102 are restricted to testing the Ethernet interface. In the present example, there are no in-service diagnostics available on the DSL loop other than performance monitoring.

Out-of-service testing (e.g., disruptive testing) may be accomplished using diagnostics associated with the device 102. The device 102 and the Ethernet service associated with the device should be out-of-service at the time of testing. This testing enables an operator to test and isolate faults on the Ethernet port and cable associated with a subscriber device 94, as well as faults associated with the DSL port and DSL physical link. If the device 102 is in-service during the test, only cable length (e.g., non-disruptive) testing may be done.

A number of out-of-service tests may be performed on the device 102. These include a port transmitter and receiver check on the Ethernet ports, which use internal loopback to enable detection of output transmitter or receiver input failures. Ethernet cable problem analysis may be performed for either non-terminated (TDR testing) or terminated cables. DSL equipment port transmitter and receiver diagnostics may be executed using internal loopback to enable detection of output transmitter or receiver input failures.

DSL link diagnostics may be executed from device 96 using single-ended loop diagnostics to determine certain characteristics of an non-terminated DSL Digital Local Loop (DLL), such as loop length, loop termination (e.g., whether the loop is an open or short circuit), loop gauge, upstream and downstream capacity (in bps), ideal upstream and downstream capacity (in bps) (e.g., capacity without considering effects of implementation loss), and dual ended loop testing.

It is understood that the method 10 of FIG. 1 may be implemented on other network configurations, such as using the transport of Ethernet frames over DS3 WAN interfaces and/or Ethernet over fiber interfaces.

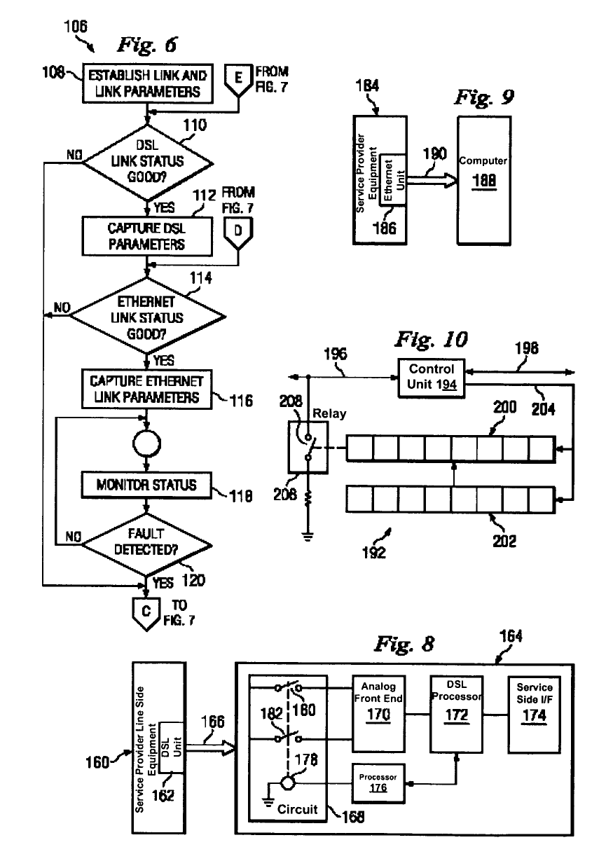

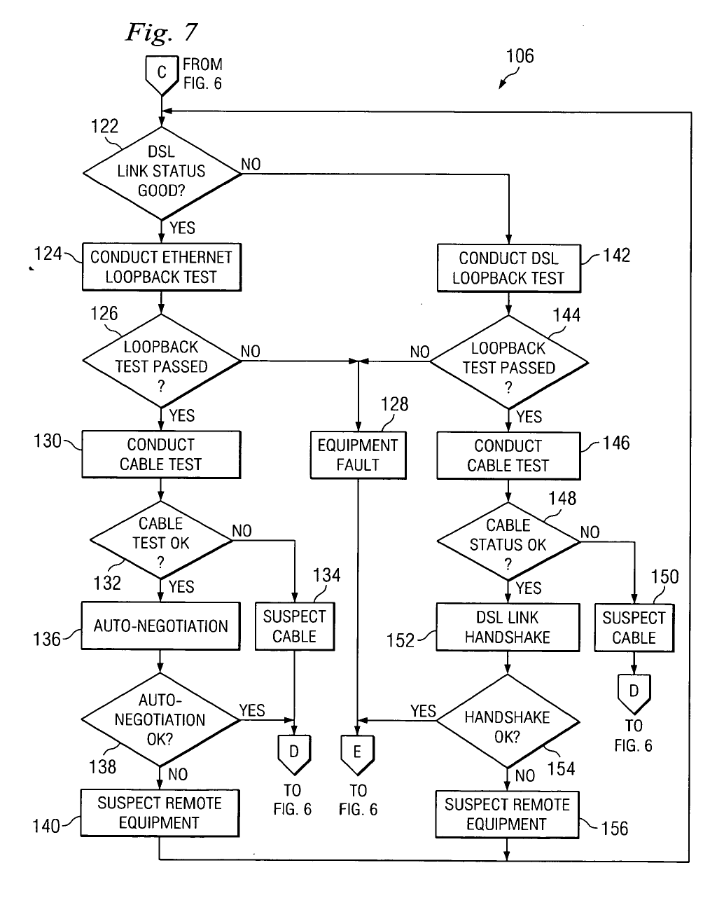

Referring now to FIGS. 6 and 7, in yet another embodiment, a method 106 utilizes steps 108-156 to enable single-ended management of the device 102 and associated components by the service provider 92 to initialize, monitor, and diagnose problems with an Ethernet interface as follows. In the present example, the method 106 is implemented by extending the capabilities provided by DSL commands in data transport services. A more detailed description of specific commands and associated information is disclosed in previously incorporated U.S. Provisional Patent Application Ser. No. (Attorney Docket No. 31873.18). It is understood that corrective measures may be taken after a fault is detected and isolated, but such measures are not explicitly denoted in FIGS. 6 and 7.

Beginning in step 108, a link is established and link parameters are determined. Before the Ethernet interface is placed in-service, the method 106 determines a current DSL link status (e.g., good or bad) in step 110. If the link status is bad, the method 106 enters a fault isolation stage, which will be described later with respect to FIG. 7. If the link status if good, the method 106 continues to step 112, where DSL parameters are captured. The method 106 then continues to step 114, where it determines whether an Ethernet link status. If the Ethernet link status is not good, then the method 106 enters the fault isolation stage that will be described later with respect to FIG. 7. If the method Ethernet status is good, the method 106 continues to step 116, where it captures Ethernet link parameters (e.g., cable status and cable length).

The method 106 then continues to steps 118, 120 and performs monitoring operations. The monitoring may check for link failure, loss of carrier and/or signal, low light conditions (for fiber optic interfaces), restart of auto-negotiation, remote fault indication, and a change in link parameters, such as cable status and length. The monitoring may also check for other faults and service degradation issues, as well as collect statistics for trend analysis. If a fault is detected in step 120, the method transitions to an out-of-service autonomous state (OOS-AU) and continues to step 122 of FIG. 7 to attempt to isolate the fault.

Referring now to FIG. 7 and with continued reference to FIG. 6, one or more tests are run automatically to determine whether the fault detected in step 120 is due to a local equipment failure, remote equipment failure, or a cable problem. In step 122, the DSL link status is determined. If the link status is good, the method 106 continues to steps 124, 126, where it conducts an Ethernet local loopback test and determines whether the test passed or failed. If it is determined in step 126 that the test failed, then the fault is likely due to an equipment fault, as indicated in step 128. The method 106 then returns to step 110.

If it is determined in step 126 that the test passed, then the method 106 conducts a cable test and determines whether the test passed or failed in steps 130, 132. If it is determined in step 132 that the test failed, then the fault is likely due to a cable problem, as indicated in step 134. The method 106 then returns to step 114. If it is determined in step 132 that the test passed, then the method continues to step 136, where it initiates an auto-negotiation procedure.

In step 138, a determination is made as to whether the auto-negotiation procedure succeeded or failed. If the auto-negotiation procedure failed, the fault is likely due to a remote equipment problem, as indicated in step 140. However, if the auto-negotiation procedure succeeded, the method returns to step 114 and checks the Ethernet link status as previously described.

Returning to step 122 of FIG. 7, if the DSL link status is determined to be bad, the method 106 proceeds to step 142, where a DSL loopback test is conducted. If it is determined in step 144 that the test failed, then the fault is likely due to an equipment fault, as indicated in step 128. The method 106 then returns to step 110.

If it is determined in step 144 that the test passed, then the method 106 conducts a cable test and determines whether the test passed or failed in steps 146, 148. If it is determined in step 148 that the test failed, then the fault is likely due to a cable problem, as indicated in step 150. The method 106 then returns to step 114. If it is determined in step 148 that the test passed, then the method continues to step 152, where it initiates a DSL link handshake. In step 154, a determination is made as to whether the handshake succeeded or failed. If the handshake failed, the fault is likely due to a remote equipment problem, as indicated in step 156. However, if the handshake succeeded, the method returns to step 110 and checks the DSL link status as previously described.

Accordingly, the method 106 of FIGS. 6 and 7 utilizes components of the network 90 of FIG. 5 to provide and manage Ethernet services. Furthermore, the method 106 enables the detection and isolation of faults to enable the service provider 92 to rapidly identify and address disruptions and potential disruptions to the Ethernet service. After a fault is detected and isolated, a detailed report may be generated regarding the fault, various fault attributes (e.g., type, location), and similar information.

Referring now to FIGS. 8-10, in still other embodiments, the performance and operation of TDRs (as described previously) may be enhanced in DSL and/or Ethernet environments as follows. TDR technology, which operates using reflected signals, is generally ineffective on properly terminated lines. Accordingly, to maximize the benefit of the TDR technology, a line that is to be characterized should not be terminated, which frequently means that a technician needs to visit a site and physically disable the connection. Once the connection is removed, tests can be run on the line. However, the process of sending a technician to remove the connection is time-consuming and expensive, and may be made more difficult if the connection is on the customer's premises or in the customer's equipment.

Referring particularly to FIG. 8, an exemplary DSL environment includes service provider line side equipment 160 and a DSL modem 164, which may be located on a subscriber's premises. The equipment 160 may be associated with a DSL unit 162, which enables the equipment 160 and modem 164 to communicate via a line 166. The modem 164 may include an analog front end 170, a DSL processor/digital signal processor 172, a service side interface (e.g., Ethernet), and a microcontroller or processor 176, as well as various connections and interfaces between these components.

In the present example, the modem 164 also includes a circuit 168, which is accessible to both the analog front end 170 and processor 176. The circuit 168 includes a relay 178 that connects two switches 180, 182 and the processor 176.

In addition to DSL traffic, the line 166 may include an out-of-band control channel (e.g., an embedded operation channel or EOC) that enables the equipment 160 to monitor and control the modem 164 via EOC messaging. In the present example, the EOC messaging may be used with the circuit 168 to enable the equipment 160 to disconnect the DSL line termination as follows.

To disconnect the line, the service provider would send a command via the EOC of line 166 to the modem 164, instructing the modem 164 to disconnect itself for an amount of time ‘t’. The time t may, for example, be predefined or may be included as a parameter in the command. Upon receiving the message, the modem 164 begins a timer and energizes the relay 178 to open the switches 180, 182. This results in a non-terminated line for a period of time defined by time t. During this time, the service provider may run diagnostics to characterize the line. When the timer expires, the processor 176 de-energizes the relay 178, which closes the switches 180, 182 and reestablishes the line. Accordingly, the effectiveness of a TDR associated with a DSL line may be enhanced by remotely affecting the line's termination.

Referring now particularly to FIGS. 9 and 10, an exemplary Ethernet environment includes server provider equipment 184 and a digital device 188. For purposes of illustration, the digital device 188 is a computer located on a subscriber's premises, but it is understood that the device 188 may be any kind of digital device applicable to the present disclosure. The equipment 184 is associated with an Ethernet unit 186 that enables the equipment 184 and computer 188 to communicate via a line 190.

In addition to various components known in the art (e.g., a processor, memory, bus, I/O device, network interface, etc., none of which are shown), the computer 188 may include a circuit 192 as illustrated in FIG. 10. In the present example, the circuit 192 is included on a network interface card (NIC) disposed in the computer 188. The NIC is associated with a media access control (MAC) number that identifies the NIC on a network. It is understood that the circuit may be associated with other components in the computer 188 or a device external to the computer 188.

The circuit 192 includes a control unit 194 that is connected to a data path indicated by lines 196, 198. The control unit 194 is also connected to a control register 200 and a timer register 202 via a line 204. The registers 200, 202 feed into a gate 206 that contains a relay 208. The relay 208 is used to disconnect line 196 from its normal termination circuitry by register 200 for the duration programmed into register 202.

To disconnect the line, the service provider may send a command via an inband signaling mechanism to the NIC and associated circuit 192. The command includes an instruction that the NIC take itself offline and an amount of time that the NIC should remain offline. Upon receiving the command, the control unit 194 loads the control and timer registers 200, 202 with appropriate values to activate the relay and place the NIC offline. This may be accomplished, for example, by altering the line impedance to appear as terminated (impedance) or not terminated (no impedance). When the period of time associated with the timer register 202 elapses, the circuit 192 de-energizes the relay 208 and places the NIC online. Accordingly, the effectiveness of a TDR associated with an Ethernet connection may be enhanced by remotely affecting the line's termination.

While the invention has been particularly shown and described with reference to the preferred embodiment thereof, it will be understood by those skilled in the art that various changes in form and detail may be made therein without departing from the spirit and scope of the invention. For example, if in-band, loopback request functionality is desired, such functionality may be obtained by combining cable testing technology with anomaly monitoring technologies to derive whether a piece of equipment is working properly. Therefore, the claims should be interpreted in a broad manner, consistent with the present invention.

1. A method for detecting and diagnosing a fault in an Ethernet service interface from a first point in a communications link, wherein the communications link includes the Ethernet service interface and terminates at a second point controlled by a customer and not accessible to the first point for detecting and diagnosing the fault, the method comprising:
monitoring the link from the first point using information about the first point and the link but not the second point to detect an occurrence of the fault;
determining a location of the fault from a set of locations that includes the first point, the second point, and the communications link;
identifying at least one fault attribute when the fault is detected, wherein the fault attribute is identified from the first point; and
categorizing one or more potential causes for the fault based on the identified fault attribute.

2. The method of claim 1 wherein the fault attribute includes a fault location.

3. The method of claim 2 wherein the fault attribute includes a fault type.

4. The method of claim 1 wherein identifying the fault attribute includes executing a diagnostics procedure from the first point to isolate the fault.

5. The method of claim 4 wherein executing the diagnostics procedure includes performing a loopback test and, depending on a result of the loopback test, checking a status of a cable forming a portion of the communications link between the first and second points.

6. The method of claim 5 wherein the cable status is checked if the loopback test indicates that no problem exists in equipment on which the loopback test was performed.

7. The method of claim 6 wherein categorizing the one or more potential causes for the fault includes using the local loopback test result or the cable status to identify whether the fault is caused by equipment associated with the first point, equipment associated with the second point, equipment positioned between the first and second points, or cable forming a portion of the communications link between the first and second points.

8. The method of claim 6 further comprising:
conducting at least one digital subscriber line (DSL) test on a DSL connection, wherein the DSL connection comprises a portion of the communications link; and
determining whether the DSL test was successful, wherein a lack of success indicates that the fault is associated with the DSL connection.

9. The method of claim 1 further comprising:
determining whether a link status is good or bad;
executing an auto-negotiation process if the link status is good;
determining whether the auto-negotiation process was successful; and
capturing at least one parameter of the communications link if the auto-negotiation process was successful.

10. The method of claim 9 wherein the at least one parameter includes at least a status of a cable forming a portion of the communications link between the first and second points or a length of the cable.

11. A method for detecting and diagnosing a fault in an Ethernet service interface that forms part of a communications system having first and second points coupled by a link, wherein the detection and diagnosis occurs from the first point within the communications system, the method comprising:
identifying a plurality of operational parameters associated with the Ethernet service interface, wherein the operational parameters establish a baseline for monitoring the Ethernet service interface;
monitoring the Ethernet service interface from the first point to detect the fault based at least partly on the operational parameters, wherein information from the second point is not available to the first point for the monitoring; and
diagnosing the detected fault from the first point, wherein the diagnosis is operable to associate the fault with a location of the fault determined from a set of locations that includes the first and second points and the link, and wherein information from the second point is not available to the first point for the diagnosing.

12. The method of claim 11 wherein the diagnosis includes executing a series of tests on the communications system, wherein the tests are operable to isolate the fault to the Ethernet service interface.

13. The method of claim 11 further comprising provisioning the Ethernet service interface from the single point.

14. A system for detecting and diagnosing a fault associated with an Ethernet service interface from a first end of a communications link, wherein the link extends from the first end and terminates at a second end, and wherein the link includes the Ethernet service interface, the system comprising:
a first communications device coupled to the first end;
a second communications device coupled to the second end, wherein devices coupled to the second end are not controllable by the first end;
a cable connecting the first and second devices; and
software associated with the first device for detecting the fault and determining a location of the fault from a set of locations that includes the first device, the second device, and the cable without using the second communications device.

15. The system of claim 14 further comprising a third communications device, wherein the second end terminates at the third device, and wherein the software is operable to determine whether the fault is associated with the third device.

16. The system of claim 15 wherein at least a portion of the cable comprises a digital subscriber line, wherein the software is operable to diagnose and detect whether the fault is associated with the digital subscriber line.

17. A method for controlling a line termination status at a remote digital device, the method comprising:
sending a command to the digital device, wherein the command includes an instruction that the digital device alter the line termination status from terminated to non-terminated;
setting a predefined period of time at the remote device;
monitoring the predefined period of time at the remote device; and
automatically altering the line termination status from non-terminated to terminated when the predefined period of time has elapsed.

18. The method of claim 17 wherein the command further includes the predefined amount of time.

19. The method of claim 17 wherein the digital device is a network interface card, and wherein the command is sent via Ethernet using an inband signaling mechanism.

20. The method of claim 17 wherein the digital device is a digital subscriber line (DSL) modem, and wherein the command is sent via a DSL channel.

21. A device for enabling remote control of a termination status of a communications link, the device comprising:
a controller operable to respond to a termination command receive via the communications link; and
a relay accessible to the controller, wherein the relay is operable to alter the termination status between terminated and non-terminated in response to the controller.

22. The device of claim 21 further comprising a timer accessible to the controller, wherein the controller directs the relay to change the status to non-terminated in response to the command, and wherein the relay changes the status to terminated after a predetermined period of time associated with the timer has elapsed.

23. The device of claim 21 further comprising an Ethernet interface operable to receive the command as a media access control frame.

24. The device of claim 21 further comprising a digital subscriber line interface operable to receive the command via a DSL channel.

25. A method for determining whether a fault in an Ethernet interface is located in service provider equipment, customer equipment, or a link coupling the service provider equipment with the customer equipment, wherein the Ethernet interface terminates at the customer equipment and the service provider has no access to the customer equipment beyond the point of termination, the method comprising:
configuring the Ethernet interface to establish an Ethernet service between the service provider equipment and the customer equipment via the link;
monitoring the Ethernet interface from the service provider equipment to detect the fault based on parameters defining a baseline for the Ethernet interface's operation, wherein the service provider equipment monitors the Ethernet interface using only information obtained from the service provider equipment and the link; and determining, using the service provider equipment, a location of the fault from a set of locations that includes the service provider equipment, the customer equipment, and the link, wherein the service provider equipment determines the location using the information.
